(19) United States
(12) Patent Application Publication
(10) Pub. No.: US 2026/0143751 A1
(43) Pub. Date: May 21, 2026

(54) THIN FILM TRANSISTOR, PANEL FOR ELECTRONIC DEVICE, AND ELECTRONIC DEVICE

(71) Applicants: SAMSUNG ELECTRONICS CO., LTD., Suwon-si (KR); POSTECH RESEARCH AND BUSINESS DEVELOPMENT FOUNDATION, Pohang-si (KR)

(72) Inventors: Gae Hwang LEE, Suwon-si (KR); Yong Young NOH, Pohang-si (KR); Kyunghun KIM, Suwon-si (KR); Soonhyo KIM, Pohang-si (KR)

(73) Assignees: SAMSUNG ELECTRONICS CO., LTD., Suwon-si (KR); POSTECH RESEARCH AND BUSINESS DEVELOPMENT FOUNDATION, Pohang-si (KR)

(21) Appl. No.: 19/323,005

(22) Filed: Sep. 9, 2025

(30) Foreign Application Priority Data
Nov. 21, 2024 (KR) 10-2024-0167788

(51) Int. Cl. H10D 30/67

(52) U.S. Cl. CPC H10D 30/675; H10D 30/6737

(57) ABSTRACT

Disclosed are a thin film transistor, a panel for an electronic device including the same, and an electronic device, the thin film transistor including a gate electrode, a semiconductor layer overlapping with the gate electrode and including a two-dimensional semiconductor material, a source electrode and a drain electrode electrically connected to the semiconductor layer, and an interlayer between the semiconductor layer and the source electrode and between the semiconductor layer and the drain electrode, respectively, and including a chalcogen atom.

### CROSS-REFERENCE TO RELATED APPLICATION

This application claims priority to and the benefit of Korean Patent Application No. 10-2024-0167788 filed in the Korean Intellectual Property Office on Nov. 21, 2024, the entire contents of which are incorporated herein by reference.

### BACKGROUND

### 1. Field

A thin film transistor, a panel for an electronic device, and an electronic device are disclosed.

### 2. Description of the Related Art

A display panel, such as an organic light emitting display panel or a quantum dot light emitting display panel, may include a plurality of pixels (subpixels) and a thin film transistor (TFT) for independently switching or driving each pixel (subpixel). One of the factors that determines the performance of the thin film transistors may be semiconductors.

### SUMMARY

Two-dimensional materials are being studied as semiconductors that may be applied to thin-film transistors. Since the two-dimensional materials may have a thin thickness of the atomic layer level, the two-dimensional materials may be lightweight, transparent, and flexible.

Some example embodiments provide a thin film transistor that may improve electrical performance while maintaining advantages of two-dimensional materials.

Some example embodiments provide a panel for an electronic device including the thin film transistor.

Some example embodiments provide an electronic device including the thin film transistor or a panel for the electronic device.

According to some example embodiments, a thin film transistor may include a gate electrode, a semiconductor layer overlapping with the gate electrode and including a two-dimensional semiconductor material, a source electrode and a drain electrode electrically connected to the semiconductor layer, and interlayers between the semiconductor layer and the source electrode and between the semiconductor layer and the drain electrode, respectively. The interlayers may include a chalcogen atom.

In some embodiments, the two-dimensional semiconductor material may include a chalcogen element, and the chalcogen atom in the interlayer may be the same as or different from the chalcogen element in the two-dimensional semiconductor material.

In some embodiments, the two-dimensional semiconductor material may be a metal chalcogenide represented by MX₂, wherein M may be at least one of Mo, W, Nb, Ti, Ta, Pt, Pd, Co, Cr, Cu, Ni, Hf, Sn, or Re, and X may be at least one of S, Se, or Te.

In some embodiments, the semiconductor layer may include one or more metal chalcogenide monolayers in which metal chalcogenides are continuously arranged along an in-plane direction of the semiconductor layer.

In some embodiments, the semiconductor layer may include one or more metal chalcogenide nanoflake layers including a plurality of metal chalcogenide nanoflakes.

In some embodiments, the interlayers may include a chalcogen layer including at least one S, Se, or Te.

In some embodiments, one surface of the interlayer may be in contact with the semiconductor layer, and an other surface of the interlayer may be in contact with the source electrode or the drain electrode.

In some embodiments, the interlayer may be thinner than the semiconductor layer.

In some embodiments, a thickness of the interlayer may be greater than or equal to 1 nm and less than 10 nm.

In some embodiments, the source electrode and the drain electrode may include two or more layers including different metals.

According to some example embodiments, a thin film transistor may include a semiconductor layer, an electrode, and an interlayer between the semiconductor layer and the electrode. The interlayer may be in contact with the semiconductor layer and the electrode. The interlayer may include a chalcogen atom.

In some embodiments, the interlayer may include a chalcogen layer, and the chalcogen layer may include at least one of S, Se, or Te.

In some embodiments, the semiconductor layer may include a metal chalcogenide represented by MX₂, wherein M may be at least one of Mo, W, Nb, Ti, Ta, Pt, Pd, Co, Cr, Cu, Ni, Hf, Sn, or Re, and X may be a chalcogen element selected from S, Se, or Te.

In some embodiments, the chalcogen atom in the interlayer may be the same as or different from the chalcogen element in the semiconductor layer.

In some embodiments, the semiconductor layer may include one or more metal chalcogenide monolayers.

In some embodiments, the semiconductor layer may include metal chalcogenide nanoflakes.

According to some example embodiments, a panel for an electronic device may include a substrate, a thin film transistor array on the substrate and a unit element array on the substrate. The thin film transistor array may include thin film transistors. The unit element array may include a plurality of unit elements electrically connected to the thin film transistors.

In some embodiments, the plurality of unit elements may include a light emitting diode, a photoelectric conversion diode, or any combination thereof.

According to some example embodiments, an electronic device may include the thin film transistor or the panel for the electronic device is provided.

Electrical performance of a thin film transistor may be improved while maintaining aspects of two-dimensional materials with atomic-level thin thickness.

### BRIEF DESCRIPTION OF THE DRAWINGS

FIG. 1 is a cross-sectional view showing an example of a thin film transistor according to some example embodiments,

FIGS. 2 and 3 are cross-sectional views showing examples of a semiconductor layer of the thin film transistor of FIG. 1,

FIGS. 4 to 6 are cross-sectional views showing other examples of thin film transistors according to some example embodiments,

FIG. 7 is a plan view showing an example of a panel for an electronic device according to some example embodiments,

FIG. 8 is a cross-sectional view showing an example of a unit element in the panel for the electronic device of FIG. 7,

FIG. 9 is a plan view showing another example of a panel for an electronic device according to some example embodiments,

FIG. 10 is a graph showing the current characteristics of the thin film transistors according to Example 1 and Comparative Example 1,

FIG. 11 is a graph showing the current characteristics of the thin film transistors according to Example 2 and Comparative Example 2,

FIG. 12 is a graph showing the distribution of current density between thin film transistors in the thin film transistor arrays according to Example 4 and Comparative Example 4, and

FIG. 13 is a graph showing the distribution of threshold voltages between thin film transistors in the thin film transistor arrays according to Example 4 and Comparative Example 4.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Example embodiments will hereinafter be described in detail, and may be easily performed by those who have common knowledge in the related art. However, this disclosure may be embodied in many different forms and is not to be construed as limited to the example embodiments set forth herein.

In the drawings, the thickness of layers, films, panels, regions, etc., are exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

Hereinafter, “combination” includes a mixture, a composite, or a stacked structure of two or more.

Hereinafter, a stretchable thin film transistor according to some example embodiments will be described with reference to the drawings.

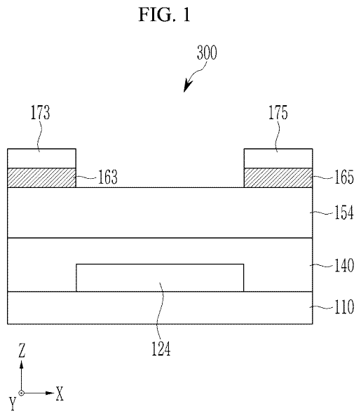

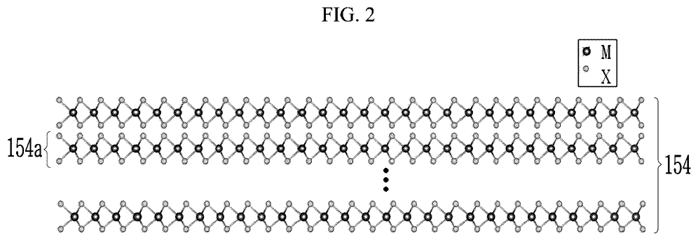

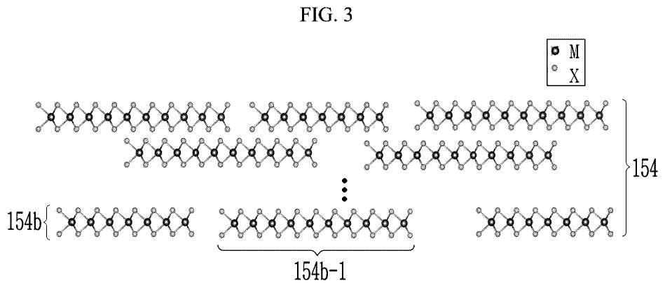

FIG. 1 is a cross-sectional view showing an example of a thin film transistor according to some example embodiments, and FIGS. 2 and 3 are cross-sectional views showing examples of a semiconductor layer of the thin film transistor of FIG. 1.

Referring to FIG. 1, a thin film transistor 300 according to some example embodiments includes a gate electrode 124, a gate insulation layer 140, a source electrode 173, a drain electrode 175, a semiconductor layer 154, and interlayers 163 and 165.

The thin film transistor 300 according to some example embodiments may be supported by a substrate 110, and the substrate 110 may be, for example, a glass substrate, a polymer substrate, or a semiconductor substrate.

The polymer substrate may be, for example, a flexible substrate and may include one or more selected from polyacrylate, polyethylene ether phthalate, polyethylene naphthalate, polycarbonate, polyarylate, polyether imide, polyether sulfone, polyimide, polyamide, and polyamide imide, but is not limited thereto.

The polymer substrate may be, for example, a stretchable substrate, and may include, for example, a polyorganosiloxane, a polymer including a butadiene structural unit, a polymer including an olefin structural unit, a polymer including a urethane structural unit, a polymer including an acrylic structural unit, or any combination thereof, and may include, for example, polydimethylsiloxane (PDMS), thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutyrene-styrene (SIBS), or any combination thereof, but is not limited thereto.

The gate electrode 124 is electrically connected to a gate line (not shown) that transmits a gate signal and is overlapped with a semiconductor layer 154 described later with a gate insulation layer 140 interposed therebetween.

The gate electrode 124 may include, for example, a conductor, for example, gold (Au), copper (Cu), nickel (Ni), aluminum (AI), molybdenum (Mo), chromium (Cr), tantalum (Ta), titanium (Ti), or an alloy thereof; a conductive nanostructure such as a conductive nanowire or a conductive nanotube; a liquid metal; a conductive polymer; or any combination thereof, but is not limited thereto. For example, the metal may be a microcracked metal having a plurality of microcracks, such as microcracked Au or an alloy thereof. The gate electrode 124 may be, for example, an elongated electrode.

The gate insulation layer 140 may be between the gate electrode 124 and the semiconductor layer 154 described later, and may be made of an organic insulator, an inorganic insulator, and/or an organic/inorganic insulator. The gate insulation layer 140 may have, for example, one layer or two or more layers.

The gate insulation layer 140 may include, for example, a high-k material, for example an oxide, nitride, or oxynitride including Ag, Mg, Cu, Zr, Zn, Hf, Cr, Al, Co, Fe, Ti, Sn, Si, Ge, Mn, W, Mo or any combination thereof, for example Ag₂O, MgO, CuO, ZrO₂, ZnO, HfO₂, Cr₂O₃, Al₂O₃, CosO₄, Fe₂O₃, TiO₂, SiO₂, SnO₂, GeO₂, MnO₂, WO₃, MoO₃, or any combination thereof, but is not limited thereto.

The gate insulation layer 140 may include, for example, a stretchable insulator, for example, polyorganosiloxane, a polymer including a butadiene structural unit, a polymer including an olefin structural unit, a polymer including a urethane structural unit, a polymer including an acrylic structural unit, or any combination thereof, and may include, for example, polydimethylsiloxane (PDMS), styrene-ethylene-butylene-styrene (SEBS), styrene-ethylene-propylene-styrene (SEPS), styrene-butadiene-styrene (SBS), styrene-isobutylene-styrene (SIBS), or any combination thereof, but is not limited thereto.

The source electrode 173 is electrically connected to a data line (not shown) that transmits a data signal and faces the drain electrode 175 with a semiconductor layer 154 described later therebetween. The source electrode 173 and the drain electrode 175 may be electrically connected to a semiconductor layer 154 described later.

The source electrode 173 and the drain electrode 175 may include, for example, a conductor such as gold (Au), copper (Cu), nickel (Ni), aluminum (AI), molybdenum (Mo), chromium (Cr), tantalum (Ta), titanium (Ti), or an alloy thereof; a conductive nanostructure such as a conductive nanowire or a conductive nanotube; a liquid metal; a conductive polymer; or any combination thereof, but is not limited thereto. For example, the metal may be a microcracked metal having a plurality of microcracks, such as microcracked gold or an alloy thereof. The source electrode 173 and the drain electrode 175 may be, for example, stretchable electrodes.

The source electrode 173 and the drain electrode 175 may each include a plurality of metal layers. The metal layer may be, for example, two to six layers, but is not limited thereto. For example, the source electrode 173 and the drain electrode 175 may include plurality of metal layers having different work functions, such as Au/Ti, Au/Ni, Au/Al, Au/Ti/Ni, Au/Ti/Al, or any combination thereof, but not limited thereto.

The semiconductor layer 154 may overlap with the gate electrode 124 and electrically connected to the source electrode 173 and the drain electrode 175, respectively. The semiconductor layer 154 may be, for example, an ultra-thin semiconductor layer with a thickness of the nanometer level.

The semiconductor layer 154 may include a two-dimensional semiconductor material. The two-dimensional semiconductor material may be a planar type inorganic semiconductor nanomaterial extending along two axes (e.g., X-axis and Y-axis), for example, a length extending along the X-axis and a width extending along the Y-axis may be significantly larger than a thickness extending along the Z-axis, and for example, the length extending along the X-axis and the width extending along the Y-axis may each be independently tens of nanometers to several micrometers, and the thickness extending along the Z-axis may be angstroms to several nanometers.

The two-dimensional semiconductor material may include a chalcogen element, such as S, Se, Te, or any combination thereof. The two-dimensional semiconductor material may include, for example, a metal chalcogenide and may include, for example, a transition metal dichalcogenide. The two-dimensional semiconductor material may be, for example, in the form of a two-dimensional nanostructure.

The metal chalcogenide may include at least one transition metal and at least one chalcogen element, and may be represented, for example, by MX₂. Here, M may be a metal (e.g., a transition metal), such as Mo, W, Nb, Ti, Ta, Pt, Pd, Co, Cr, Cu, Ni, Hf, Sn, Re, or any combination thereof, and X may be a chalcogen element, such as S, Se, Te, or any combination thereof.

The metal chalcogenide may include, for example, MoS₂, MoSe₂, MoSSe, MoSTe, Mo₍₁₋ₓ₎WₓS₂, Mo₍₁₋ₓ₎WₓSe₂, Mo₍₁₋ₓ₎WₓTe₂, Mo₍₁₋ₓ₎NbₓS₂, Mo₍₁₋ₓ₎NbₓSe₂, Mo₍₁₋ₓ₎TₐₓS₂, Mo₍₁₋ₓ₎TaₓSe₂, Mo₍₁₋ₓ₎WₓSSe, MoTe₂, WS₂, WSe₂, WSSe, WTe₂, WSTe, W₍₁₋ₓ₎NbₓS₂, W₍₁₋ₓ₎NbₓSe₂, PtS₂, PtSe₂, PtTe₂, PdSe₂, TaS₂, TaSe₂, Ta₍₁₋ₓ₎WₓS₂, Ta₍₁₋ₓ₎WₓSe₂, HfS₂, HfSe₂, HfTe₂, TiS₂, TiSe₂, TiTe₂, NbS₂, NbSe₂, NbTe₂, SnS₂, SnSe₂, SnTe₂, ReS₂, ReSe₂, ReTe₂ (wherein 0≤x≤1), or any combination thereof, but is not limited thereto.

For example, referring to FIG. 2, the semiconductor layer 154 may include one or more metal chalcogenide monolayers 154a. The metal chalcogenide monolayer 154a may be arranged continuously along the in-plane direction (e.g., XY direction) of the semiconductor layer 154 with a metal chalcogenide represented by MX₂, for example, and a van der Waals gap with a spacing of several angstroms may be formed between adjacent metal chalcogenide monolayers 154a, thereby controlling the electrical characteristics of the semiconductor layer 154.

For example, referring to FIG. 3, the semiconductor layer 154 may include one or more metal chalcogenide nanoflake layers 154b including a plurality of metal chalcogenide nanoflakes 154b-1. The metal chalcogenide nanoflakes 154b-1 may be very thin exfoliated flakes obtained by exfoliating bulk metal chalcogenide crystals, and may be obtained, for example, by a mechanical exfoliation and/or a solution-phase exfoliation. A plurality of metal chalcogenide nanoflakes 154b-1 may be arranged along the in-plane direction (XY direction) of the semiconductor layer 154, and adjacent metal chalcogenide nanoflakes 154b-1 in the metal chalcogenide nanoflake layer 154b may be separated from each other or partially covered. Adjacent metal chalcogenide nanoflake layers 154b may be spaced apart by a distance of angstroms to several nanometers, and a van der Waals gap may be formed between adjacent metal chalcogenide nanoflake layers 154b, which may control the electrical properties of the semiconductor layer 154.

A thickness of the semiconductor layer 154 may be about 1 nm to about 30 nm, and within the above range may be about 1 nm to about 25 nm, about 1 nm to about 20 nm, about 1 nm to about 15 nm, or about 1 nm to about 10 nm.

The interlayers 163 and 165 may be between the semiconductor layer 154 and the source electrode 173 and between the semiconductor layer 154 and the drain electrode 175, respectively. For example, the interlayer 163 may be in contact with the semiconductor layer 154 and the source electrode 173, respectively, and the interlayer 165 may be in contact with the semiconductor layer 154 and the drain electrode 175, respectively. That is, one surface of the interlayers 163 and 165 may be in contact with the semiconductor layer 154, and the other surface of the interlayers 163 and 165 may be in contact with the source electrode 173 or the drain electrode 175.

The interlayers 163 and 165 may include a chalcogen element. The chalcogen element(s) in the interlayers 163 and 165 may be the same as or different from the chalcogen element(s) in the two-dimensional semiconductor material of the semiconductor layer 154, and may each independently include S, Se, Te, or any combination thereof. The chalcogen element in the interlayers 163 and 165 may be referred to as a chalcogen atom to distinguish from the chalcogen elements in the two-dimensional semiconductor material of the semiconductor layer 154.

For example, the interlayers 163 and 165 may include a chalcogen layer composed of a chalcogen element including S, Se, Te, or any combination thereof, and the chalcogen layer may be a layer in which S, Se, Te, or any combination thereof are covalently bonded.

For example, the interlayers 163 and 165 may include a sulfur layer composed of sulfur(S). For example, the interlayers 163 and 165 may include a selenium layer composed of selenium (Se). For example, the interlayers 163 and 165 may include a tellurium layer composed of tellurium (Te). For example, the interlayers 163 and 165 may include a sulfur-selenium layer composed of sulfur(S) and selenium (Se). For example, the interlayers 163 and 165 may include a sulfur-tellurium layer composed of sulfur(S) and tellurium (Te). For example, the interlayers 163 and 165 may include a selenium-tellurium layer composed of selenium (Se) and tellurium (Te). For example, the interlayers 163 and 165 may include a sulfur-selenium-tellurium layer composed of sulfur(S), selenium (Se), and tellurium (Te).

The interlayers 163 and 165 may be a deposition layer, for example, a thermal deposition layer formed by thermal deposition. The interlayers 163 and 165 may be formed into a thin and uniform film by deposition (e.g., thermal deposition) to have good coverage, and thus may effectively cover the ultra-thin semiconductor layer 154 with a thickness of nanometer level positioned thereunder.

In addition, the interlayers 163 and 165 are on the semiconductor layer 154 so as to more effectively limit and/or prevent damage to the two-dimensional semiconductor material of the semiconductor layer 154 in a subsequent process for forming the source electrode 173 and the drain electrode 175, while effectively blocking the metal for the source electrode 173 and the drain electrode 175 from diffusing into the two-dimensional semiconductor material of the semiconductor layer 154, thereby limiting and/or preventing deterioration of the electrical characteristics of the thin film transistor 300.

In addition, the interlayers 163 and 165 may effectively lower the contact resistance between the semiconductor layer 154 and the source electrode 173 and between the semiconductor layer 154 and the drain electrode 175, thereby improving the electrical characteristics of the thin film transistor 300.

In addition, the interlayers 163 and 165 and the semiconductor layer 154 may reduce the heterogeneity at the interface between the interlayers 163 and 165 and the semiconductor layer 154 by including the same or different chalcogen elements, thereby having a substantially seamless interface, and thus effectively lowering the contact resistance, thereby improving the electrical characteristics of the thin film transistor 300.

The interlayers 163 and 165 may be thinner than the semiconductor layer 154. For example, the thickness of the interlayers 163 and 165 may be less than about 30 nm, and within the range may be about 1 nm to about 25 nm, about 1 nm to about 20 nm, about 1 nm to about 15 nm, about 1 nm to about 10 nm, about 1 nm to about 8 nm, about 1 nm to about 7 nm, or about 1 nm to about 5 nm. For example, the thickness of the interlayers 163 and 165 may be less than about 10 nm, and within the above range may be greater than or equal to about 1 nm and less than about 10 nm, about 1 nm to about 8 nm, about 1 nm to about 7 nm, or about 1 nm to about 5 nm.

In FIG. 1, a thin film transistor with a bottom gate and top contact structure is illustrated as an example of a thin film transistor 300, but the present disclosure is not limited thereto and may be applied to thin film transistors with various structures.

Another example of a thin film transistor according to some example embodiments is described.

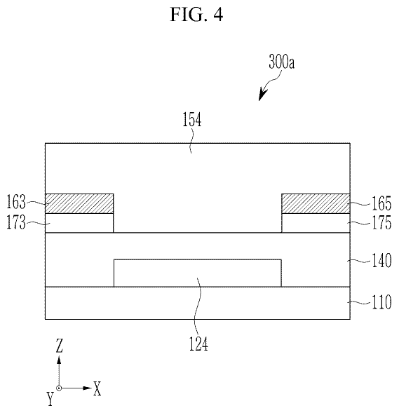

FIGS. 4 to 6 are cross-sectional views showing other examples of thin film transistors according to some example embodiments.

Referring to FIGS. 4 to 6, thin film transistor 300a, 300b, and 300c according to the present examples includes a gate electrode 124, a gate insulation layer 140, a source electrode 173, a drain electrode 175, a semiconductor layer 154, and interlayers 163 and 165, similar to the examples described above. The descriptions of the gate electrode 124, gate insulation layer 140, source electrode 173, drain electrode 175, semiconductor layer 154, and interlayers 163 and 165 are as described above.

However, referring to FIG. 4, the thin film transistor 300a according to the present example may have a bottom gate and bottom contact structure in which a gate electrode 124, a gate insulation layer 140, a source electrode and a drain electrode 173 and 175, interlayers 163 and 165, and a semiconductor layer 154 are sequentially stacked on a substrate 110, and the semiconductor layer 154 is electrically connected to the source electrode 173 and the drain electrode 175 thereunder. The interlayers 163 and 165 may be between the semiconductor layer 154 and the source electrode 173 and between the semiconductor layer 154 and the drain electrode 175, as in the above-described example.

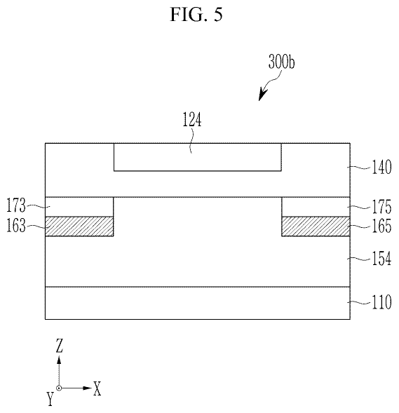

Referring to FIG. 5, a thin film transistor 300b according to the present example may have a top gate and top contact structure in which a semiconductor layer 154, interlayers 163 and 165, a source electrode and a drain electrode 173 and 175, a gate insulation layer 140, and a gate electrode 124 are sequentially stacked on a substrate 110, and the semiconductor layer 154 is electrically connected to the source electrode 173 and the drain electrode 175 thereon.

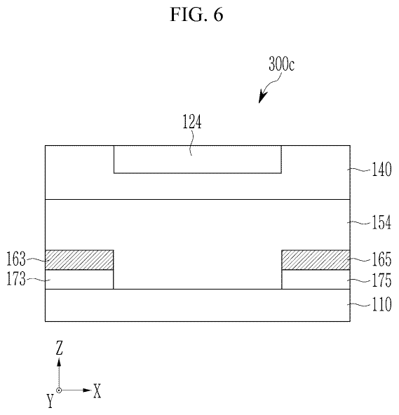

Referring to FIG. 6, a thin film transistor 300c according to the present example may have a top gate and bottom contact structure in which a source electrode and a drain electrode 173 and 175, interlayers 163 and 165, a semiconductor layer 154, a gate insulation layer 140, and a gate electrode 124 are sequentially stacked on a substrate 110, and the semiconductor layer 154 is electrically connected to the source electrode 173 and the drain electrode 175 thereunder.

The aforementioned thin film transistors 300, 300a, 300b, and/or 300c may be repeatedly arranged, for example, along rows and/or columns, on a substrate 110 to form a thin film transistor array. The thin film transistor array may be incorporated in a panel for an electronic device.

For example, the panel for the electronic device may be a flexible panel.

For example, the panel for the electronic device may be a stretchable panel.

For example, the panel for the electronic device may be a display panel, a sensor array panel, or a sensor embedded display panel.

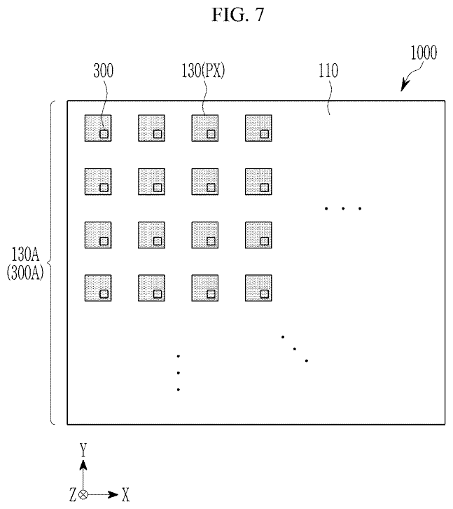

FIG. 7 is a plan view showing an example of a panel for an electronic device according to some example embodiments.

Referring to FIG. 7, a panel 1000 for an electronic device according to some example embodiments includes a substrate 110, a thin film transistor array 300A arranged on the substrate 110, and a unit element array 130A.

The substrate 110 may be, for example, a glass substrate, a polymer substrate, or a semiconductor substrate as described above, and the polymer substrate may be, for example, a flexible substrate or a stretchable substrate.

The thin film transistor array 300A includes a plurality of thin film transistors 300 arranged, for example, along rows and/or columns, each thin film transistor 300 as described above. While FIG. 7 illustrates the thin film transistor 300 described in connection with FIG. 1, example embodiments are not limited thereto. The thin film transistor array 300A may include any one of the thin film transistors 300, 300a, 300b, and/or 300c described above and any combination thereof.

The unit element array 130A includes a plurality of unit elements 130 arranged, for example, along rows and/or columns, and each unit element may be a light emitting diode, such as an organic light emitting diode, an inorganic light emitting diode, a quantum dot light emitting diode, a micro light emitting diode, or a perovskite light emitting diode, or a photoelectric conversion diode, such as an organic photoelectric conversion diode, an inorganic photoelectric conversion diode, or an organic/inorganic photoelectric conversion diode, and may be the same or different from each other. Each unit element 130 may define a pixel or a subpixel PX.

For example, each unit element 130 may be a light emitting diode configured to independently display red, green, blue, or any combination thereof.

For example, each unit element 130 may be a photoelectric diode configured to selectively absorb red, green, blue, infrared, or any combination thereof light and convert the absorbed light into an electrical signal.

For example, some of the unit elements 130 may be light emitting diodes and some of the unit elements 130 may be photoelectric conversion diodes.

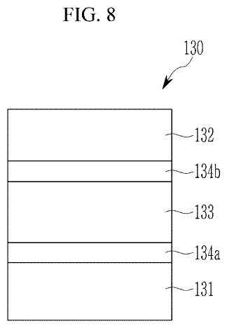

FIG. 8 is a cross-sectional view showing an example of a unit element in the panel for the electronic device of FIG. 7.

Referring to FIG. 8, the unit element 130 may be a light emitting diode or a photoelectric conversion diode and may include an anode 131; a cathode 132; an active layer 133 between the anode 131 and the cathode 132, and optionally auxiliary layers 134a and 134b between the anode 131 and the active layer 133 and/or between the cathode 132 and the active layer 133.

At least one of the anode 131 or the cathode 132 may be a light transmitting electrode. For example, the anode 131 may be a light transmitting electrode and the cathode 132 may be a reflective electrode. For example, the anode 131 may be a reflective electrode and the cathode 132 may be a light transmitting electrode. For example, the anode 131 and cathode 132 may each be light transmitting electrodes. At least one of the anode 131 or the cathode 132 may be a stretchable electrode, and the stretchable electrode may have, for example, a plurality of microcracks, and the plurality of microcracks are separated from each other like small holes, so that electrical conduction paths in the electrode may be maintained and the microcracks may expand along the stretching direction during stretching, thereby imparting flexibility to the electrode.

The active layer 133 may be a light emitting layer or a photoelectric conversion layer.

The light emitting layer may be configured to emit light in a red wavelength region, a green wavelength region, a blue wavelength region, an infrared wavelength region, or any combination thereof, and may include, for example, an organic light emitting layer, an inorganic light emitting layer (including a quantum dot light emitting layer), an organic/inorganic light emitting layer, or any combination thereof. The light emitting layer may include at least one host material and at least one dopant.

The photoelectric conversion layer may be configured to absorb light in a red wavelength region, a green wavelength region, a blue wavelength region, an infrared wavelength region, or any combination thereof, and may be configured to convert the absorbed light into an electrical signal, and may be an organic photoelectric conversion layer, an inorganic photoelectric conversion layer, an organic/inorganic photoelectric conversion layer, or any combination thereof. The photoelectric conversion layer may include a p-type semiconductor and an n-type semiconductor, and the p-type semiconductor and the n-type semiconductor may form a pn junction.

The auxiliary layers 134a and 134b may be, for example, charge auxiliary layers, and may be, for example, a hole transport layer, a hole injection layer, an electron blocking layer, an electron transport layer, an electron injection layer, a hole blocking layer, or any combination thereof, but are not limited thereto.

Each unit element 130 may be independently controlled and/or driven by one or more thin film transistors, at least some of which may be any one of the aforementioned thin film transistors 300, 300a, 300b, and/or 300c. For example, at least one thin film transistors 300, 300a, 300b, and/or 300c may be included in each pixel (subpixel), and each unit element 130 and the thin film transistor 300, 300a, 300b, or 300c may be electrically connected. The description of the thin film transistors 300, 300a, 300b, or 300c is as described above.

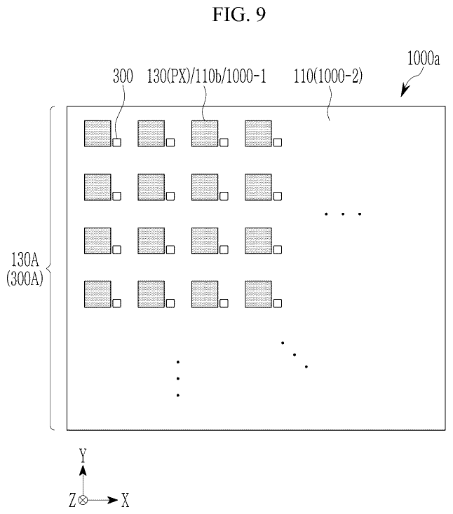

FIG. 9 is a plan view showing another example of a panel for an electronic device according to some example embodiments.

Referring to FIG. 9, the panel 1000a for an electronic device according to the present example includes, similar to the example panel 1000 described above, a substrate 110, a thin film transistor array 300A arranged on the substrate 110, and a unit element array 130A. While FIG. 9 illustrates the thin film transistor 300 described in connection with FIG. 1, example embodiments are not limited thereto. The thin film transistor array 300A in the panel 1000a may include any one of the thin film transistors 300, 300a, 300b, and/or 300c described above and any combination thereof.

However, the panel 1000a for an electronic device according to the present example may be a stretchable electronic device panel, and the substrate 110 may be a stretchable substrate.

A panel 1000a for an electronic device may include regions having different elastic moduli along an in-plane direction (e.g., XY direction) of a substrate 110, and may include a high elastic modulus region 1000-1 having a relatively high elastic modulus and a low elastic modulus region 1000-2 having a relatively low elastic modulus.

The high elastic modulus region 1000-1 may be a region in which resistance to external force such as twisting, pressing, and/or pulling is relatively high, so that it may not be substantially deformed by the external force or a deformation degree may be very small. That is, the high elastic modulus region 1000-1 may include a stretch resistance region with very low stretchability due to a large resistance to stretching, in addition to a region with no stretchability at all.

The high elastic modulus regions 1000-1 may be a region in which a non-stretchable patterns 110b having a high elastic modulus are covered on a substrate 110, and accordingly, the high elastic modulus regions 1000-1 may have substantially the same planar shape as the non-stretchable patterns 110b.

The elastic modulus of the high elastic modulus region 1000-1 may be determined by the elastic modulus of the non-stretchable pattern 110b. For example, the elastic modulus of the non-stretchable pattern 110b may be about 100 times or more, within the above range, about 300 times or more, about 500 times or more, or about 1000 times or more, and within the above range, about 100 times to about 10⁸ times, about 500 times to about 10⁸ times, about 1000 times to about 10⁸ times, about 10 times to about 10⁷ times, about 50 times to about 10⁷ times, about 100 times to about 10⁷ times, about 500 times to about 10⁷ times, or about 10³ times to about 10⁷ times, higher than that of the substrate 110. For example, the elastic modulus of the non-stretchable pattern 110b may be about 10⁴ Pa to about 10¹² Pa, but is not limited thereto. Due to the high elastic modulus of the non-stretchable pattern 110b, the high elastic modulus region 1000-1 may not be substantially stretched or deformed even if the substrate 110 is stretched in a desired and/or alternatively predetermined direction.

The non-stretchable patterns 110b may include an organic material, an inorganic material, an organic/inorganic material, or any combination thereof, with a relatively high elastic modulus, for example polycarbonate, polymethylmethacrylate, polyethyleneterephthalate, polyethylenenaphthalate, polyimide, polyamide, polyamideimide, polyethersulfone, or any combination thereof, but is not limited thereto.

The non-stretchable patterns 110b may be formed by, for example, coating or depositing a material (e.g., an organic material) with a relatively high elastic modulus on the substrate 110 and partially removing it by, for example, etching, to leave the non-stretchable patterns 110b only in the portion corresponding to the high elastic modulus regions 1000-1. However, the present disclosure is not limited thereto, and the high elastic modulus regions 1000-1 and the low elastic modulus regions 1000-2 having different elastic moduli may be implemented by forming the non-stretchable patterns 110b on the substrate 110 in various ways.

The high elastic modulus regions 1000-1 may be arranged, for example, along rows and/or columns, and the unit elements 130 may be arranged therein. The unit element 130 arranged in a high elastic modulus region 1000-1 may define a pixel or subpixel.

The low elastic modulus region 1000-2 is a region that may flexibly respond to external forces such as twisting, pressing, and/or pulling, and may be a region excluding the high elastic modulus regions 1000-1. The low elastic modulus region 1000-2 may be a region where the non-stretchable patterns 110b are not covered on the substrate 110 and may be relatively evenly arranged on the entire surface of the panel 1000 for the electronic device.

The elastic modulus of the low elastic modulus region 1000-2 may be substantially equal to the elastic modulus of the substrate 110. The substrate 110 may include an elastomer with a relatively low elastic modulus, for example, an elastomer (including organic-inorganic elastomer), an inorganic elastomer-like material, or any combination thereof.

The elastomer may include for example polyorganosiloxane, a polymer including a butadiene structural unit, a polymer including an olefin structural unit, a polymer including a urethane structural unit, a polymer including an acrylic structural unit, or any combination thereof, for example polydimethylsiloxane, thermoplastic polyurethane (TPU), a styrene-ethylene-butylene-styrene (SEBS), styrene-ethylene-propylene-styrene (SEPS), styrene-butadiene-styrene (SBS), styrene-isoprene-styrene (SIS), styrene-isobutyrene-styrene (SIBS), or any combination thereof, but is not limited thereto. The inorganic elastomer-like material may include, for example, a ceramic having elasticity, a solid metal, a liquid metal, or any combination thereof, but not limited thereto. An elastic modulus of the elastomer may be, for example, about 100 Pa to about 10⁹ Pa, but is not limited thereto.

The low elastic modulus region 1000-2 may be surrounded and isolated by the high elastic modulus regions 1000-1, but is not limited thereto. Conversely, the high elastic modulus regions 1000-1 may be surrounded and isolated by the low elastic modulus region 1000-2.

The thin film transistor array 300A may be arranged in a high elastic modulus region 1000-1 and/or a low elastic modulus region 1000-2. For example, at least some of the thin film transistors 300 of the thin film transistor array 300A may be arranged in the low elastic modulus region 1000-2. As described above, since the thin film transistor 300 includes a two-dimensional semiconductor material in the semiconductor layer 154, the thin film transistor 300 may have stretchability, and may be flexibly stretched and restored against external force by being disposed in the low elastic modulus region 1000-2.

In this way, by disposing at least some of the thin film transistors 300, 300a, 300b, and/or 300c of the thin film transistor array 300A in an area other than the pixel PX, namely the low elastic modulus region 1000-2, the area occupied by the thin film transistors in the pixel PX may be reduced compared to a structure in which all thin film transistors are disposed in the pixel PX.

Therefore, the limitation of pixel arrangement space due to the low elastic modulus region 1000-2 for stretching may be overcome, the pixel size may be reduced, and the number of pixels per unit area may be increased accordingly. For example, the number of pixels (subpixels) per unit area in the panel 1000a for an electronic device may be greater than or equal to about 150 ppi (pixel per inch), greater than or equal to about 200 ppi, greater than or equal to about 250 ppi, greater than or equal to about 300 ppi, greater than or equal to about 350 ppi, greater than or equal to about 400 ppi, greater than or equal to about 450 ppi, or greater than or equal to about 500 ppi and may be, for example, about 150 ppi to about 1000 ppi, about 200 ppi to about 1000 ppi, about 250 ppi to about 1000 ppi, about 300 ppi to about 1000 ppi, about 350 ppi to about 1000 ppi, about 400 ppi to about 1000 ppi, about 450 ppi to about 1000 ppi, or about 500 ppi to about 1000 ppi.

The panel for an electronic device 1000 and/or 1000a according to the present example may be applied to various fields, and may be, for example, a display panel, a sensor array, or a display panel equipped with a sensor. The panel for an electronic device 1000 may be, for example, a panel for a stretchable electronic device, for example, a bendable display panel, a foldable display panel, a rollable display panel, a wearable device panel, a skin-type stretchable display panel, a skin-like display panel, a skin-like sensor array, a large-area conformable display, smart clothing, or the like, but is not limited thereto. For example, the stretchable sensor array may be attached to a living body in the form of a very thin patch or band to monitor biometric information in real time, and may be a sensor array including, for example, a photoplethysmographic sensor (PPG sensor), and the biometric information may include heart rate, oxygen saturation, stress, arrhythmia, blood pressure, etc., and the biometric information may be obtained by analyzing the waveform of the electrical signal.

The aforementioned thin film transistors 300, 300a, 300b, and/or 300c, or panel for the electronic device 1000 and/or 1000a may be included in various electronic devices, and the electronic device may further include a processor (not shown) and a memory (not shown).

The electronic devices may include, for example, mobile phones, video phones, smart phones, smart pads, smart watches, digital cameras, tablet PCs, laptop PCs, notebook computers, computer monitors, wearable computers, televisions, digital broadcasting terminals, e-books, and personal digital assistants (PDAs), PMP (portable multimedia player), EDA (enterprise digital assistant), head mounted displays (HMD), in-vehicle navigations, Internet of Things (IoT), Internet of Everything (IoE), security devices, medical devices, but are not limited thereto.

Hereinafter, the embodiments are illustrated in more detail with reference to examples. However, these examples are exemplary, and the present scope is not limited thereto.

### Preparation of Two-Dimensional Semiconductor Materials

### Preparation Example 1

Tetraethylammonium bromide (THAB made by TCI, purity of 98%) is dissolved in acetonitrile at a concentration of 5 mg/mL to prepare a THAB solution. Subsequently, after preparing a copper tape as an anode and a graphite rod as a cathode, bulk WSe₂ is attached to one surface of the copper tape (anode) to form an assembly of anode/WSe₂/cathode, then the assembly is dipped in the THAB solution. Then, when a voltage of −15 V is applied between the cathode and anode for 1 hour, the bulk WSe₂ swells, which is transferred to an 8 mg/mL PVP/DMF solution and dispersed in the solution by using an ultrasonicator to prepare a WSe₂ nanoflake dispersion. Subsequently, the WSe₂ nanoflake dispersion is placed in a centrifuge and sequentially centrifuged at 1000 rpm, 2000 rpm, and 3000 rpm to remove precipitates and finally centrifuged at 5000 rpm, and the obtained precipitates are redispersed in an isopropylalcohol (IPA) solvent to prepare a WSe₂ nanoflake ink.

### Preparation Example 2

WSe₂ nanoflakes are prepared by fixing bulk WSe₂ on a 3M Scotch tape, repeating a process of attaching and detaching another 3M Scotch tape thereto to repeatedly reduce the number of bulk WSe₂ layers and then, performing mechanical exfoliation.

### Manufacturing of Thin Film Transistor

### Example 1

SiO₂ is deposited on a p-type doped silicon wafer to form a 100 nm-thick gate insulation layer. On the gate insulation layer, a photoresist is applied, exposed, and developed to form photoresist patterns in a region (semiconductor region) where a semiconductor layer is to be formed. Subsequently, on the gate insulation layer and the photoresist patterns, the WSe₂ nanoflake ink according to Preparation Example 1 is applied in a drop casting to form a WSe₂ nanoflake layer. The photoresist patterns are removed through lift-off to selectively form the WSe₂ nanoflake layer in the semiconductor region. Then, a heat treatment at 200° C. for 10 minutes under a nitrogen atmosphere is performed to form a 40 nm-thick semiconductor layer in which the 3 or 4 WSe₂ nanoflakes are stacked. Subsequently, a chromium shadow mask (length: 10 μm, width: 500 μm) is placed on the silicon wafer, and a 3 nm-thick interlayer is formed in a region (electrode region) where an electrode will be formed through chalcogen deposition in a high-vacuum thermal evaporator. The chalcogen deposition is performed at a rate of 0.1 Å/s to 0.2 Å/s under a thermal evaporator internal pressure of 1×10−6 torr or less by placing a selenium (Se) powder source in a quartz crucible. Subsequently, on the interlayer, Au is deposited to form a 20 nm-thick source and drain electrodes, manufacturing a thin film transistor.

### Comparative Example 1

A thin film transistor is manufactured in the same manner as in Example 1 except that the interlayer is not formed.

### Example 2

A thin film transistor is manufactured in the same manner as in Example 1 except that the source and drain electrodes are additionally annealed at 180° C. for 30 minutes after the formation of the source and drain electrodes.

### Comparative Example 2

A thin film transistor is manufactured in the same manner as in Example 2 except that the interlayer is not formed.

### Example 3-1

SiO₂ is deposited on a p-type doped silicon wafer to form a 100 nm-thick gate insulation layer. Subsequently, the WSe₂ nanoflakes according to Preparation Example 2 are transferred onto a semiconductor region of the gate insulation layer to form a 3 nm-thick semiconductor layer (channel length: 1.5 μm). Then, a photoresist is applied onto the silicon wafer and then, exposed and developed to form photoresist patterns selectively exposing an electrode region. Subsequently, chalcogen deposition proceeds in a high vacuum thermal depositor to form a 3 nm-thick interlayer in the electrode region. The chalcogen deposition is performed at a rate of 0.1 Å/s to 0.2 Å/s under an internal pressure 1×10⁻⁶ torr or less by placing a selenium (Se) powder source in a quartz crucible. Subsequently, Au is deposited on the interlayer, and the photoresist patterns are removed through lift-off to form a 20 nm-thick source and drain electrode, manufacturing a thin film transistor.

### Example 3-2

A thin film transistor is manufactured in the same manner as in Example 3-1 except that a 5-nm thick semiconductor layer is formed instead of the 3 nm-thick semiconductor layer.

### Example 3-3

A thin film transistor is manufactured in the same manner as in Example 3-1 except that a 10-nm thick semiconductor layer is formed instead of the 3 nm-thick semiconductor layer.

### Example 3-4

A thin film transistor is manufactured in the same manner as in Example 3-1 except that a 20-nm thick semiconductor layer is formed instead of the 3 nm-thick semiconductor layer.

### Comparative Example 3

A thin film transistor is manufactured in the same manner as in Example 3-1 except that the interlayer is not formed.

### Evaluation I

The thin film transistors of Examples and Comparative Examples are evaluated with respect to electrical characteristics.

The electrical characteristics are evaluated in a glove box under a nitrogen atmosphere with a moisture content of 5 to 10 ppm by using 4200-SCS semiconductor characteristic analyzer made by Keithley Instruments, LLC.

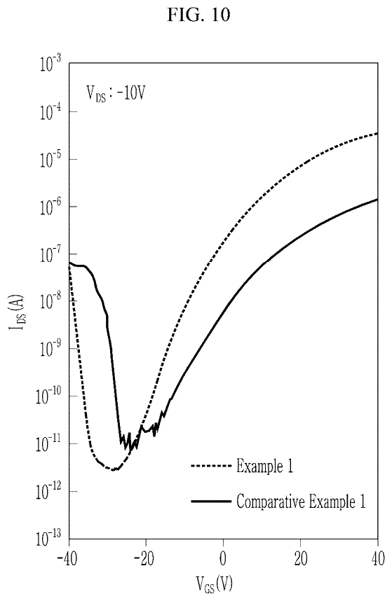

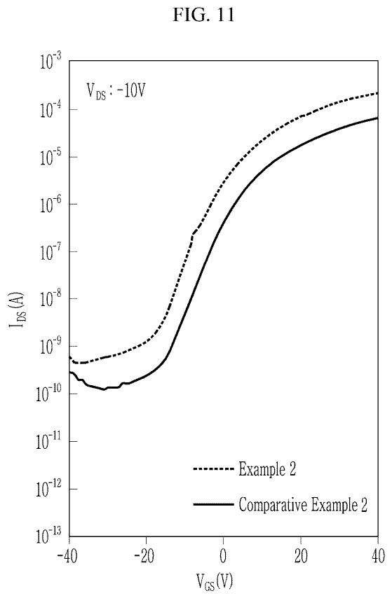

The results are shown in Tables 1 and 2 and FIGS. 10 and 11.

FIG. 10 is a graph showing the current characteristics of the thin film transistors according to Example 1 and Comparative Example 1, and FIG. 11 is a graph showing the current characteristics of the thin film transistors according to Example 2 and Comparative Example 2.

TABLE 1

| | | Field-effect | Threshold |
|---|---|---|---|
| | Current density (A/μm) | mobility | voltage |
| | (V_{GS} = −30 V, V_{DS} = −1 V) | (cm²/Vs) | (V) |
| Example 1 | 94.8 × 10⁻⁹ | 0.12 | 18 |
| Comparative | 4.9 × 10⁻⁹ | 0.017 | 23 |
| Example 1 | | | |

TABLE 2

| | | Field-effect | Threshold | |
|---|---|---|---|---|
| | Current density (A/μm) | mobility | voltage | |
| | (V_{GS} = −30 V, V_{DS} = −1 V) | (cm²/Vs) | (V) | |
| Example 3-1 | 14.3 × 10⁻⁶ | 31 | −8.8 | V |
| Example 3-2 | 29.2 × 10⁻⁶ | 54 | −4.4 | V |
| Example 3-3 | 13.8 × 10⁻⁶ | 33 | −8.1 | V |
| Example 3-4 | 17.7 × 10⁻⁶ | 40 | −12 | V |
| Comparative | 2.3 × 10⁻⁶ | 8.2 | −16.5 | V |
| Example 3 | | | | |

Referring to Tables 1 and 2, the thin film transistors according to Examples exhibit a higher on-state current value and field-effect mobility and a lower threshold voltage, compared to the thin film transistor according to Comparative Examples. It may be confirmed that the thin film transistors including the interlayer exhibit improved electrical characteristics.

Referring to FIGS. 10 and 11, the thin film transistors of Examples 1 and 2, compared with the thin film transistors of Comparative Examples 1 and 2, are confirmed to exhibit improved current characteristics.

### Manufacturing of Thin Film Transistor Arrays

### Example 4

A thin film transistor array is manufactured by forming a plurality of thin film transistors according to Example 3-2 on a p-type doped silicon wafer.

### Comparative Example 4

A thin film transistor array is manufactured by forming a plurality of thin film transistors according to Comparative Example 3 on a p-type doped silicon wafer.

### Evaluation II

The thin film transistor arrays according to Example 4 and Comparative Example 4 are evaluated with respect to electrical characteristic distribution between thin film transistors.

The electrical characteristic distribution is evaluated from current density and threshold voltage distributions of the thin film transistors in the thin film transistor arrays.

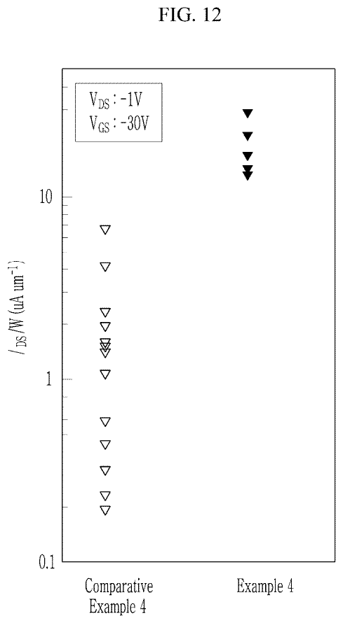

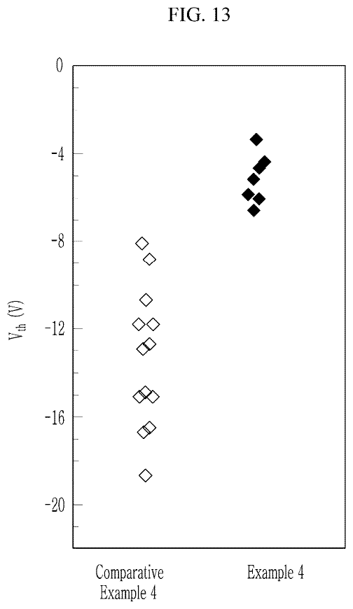

The results are shown in FIGS. 12 and 13.

FIG. 12 is a graph showing the distribution of current density between thin film transistors in the thin film transistor arrays according to Example 4 and Comparative Example 4, and FIG. 13 is a graph showing the distribution of threshold voltages between thin film transistors in the thin film transistor arrays according to Example 4 and Comparative Example 4.

Referring to FIGS. 12 and 13, the current density and threshold voltage of the thin film transistor array of Example 4 are distributed within a relatively narrow range, but the current density and threshold voltage of thin film transistor array of Comparative Example 4 are distributed within a relatively wide range.

Accordingly, the thin film transistor array of Example 4 has a smaller distribution of electrical characteristic, compared with the thin film transistor array of Comparative Example 4, and from this, it may be expected that the reliability of the thin film transistor array of Example 4 is higher than the thin film transistor array of Comparative Example 4.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A thin film transistor, comprising:
a gate electrode,
a semiconductor layer overlapping with the gate electrode, the semiconductor layer comprising a two-dimensional semiconductor material,
a source electrode and a drain electrode electrically connected to the semiconductor layer, and
an interlayer between the semiconductor layer and the source electrode and between the semiconductor layer and the drain electrode, respectively, wherein
the interlayer comprises a chalcogen atom.

2. The thin film transistor of claim 1, wherein
the two-dimensional semiconductor material comprises a chalcogen element, and
the chalcogen atom in the interlayer is same as or different from the chalcogen element in the two-dimensional semiconductor material.

3. The thin film transistor of claim 2, wherein
the two-dimensional semiconductor material is a metal chalcogenide represented by MX₂,
M is at least one of Mo, W, Nb, Ti, Ta, Pt, Pd, Co, Cr, Cu, Ni, Hf, Sn, or Re, and
X is at least one of S, Se, or Te.

4. The thin film transistor of claim 3, wherein
the semiconductor layer comprises one or more metal chalcogenide monolayers in which metal chalcogenides are continuously arranged along an in-plane direction of the semiconductor layer.

5. The thin film transistor of claim 3, wherein the semiconductor layer comprises one or more metal chalcogenide nanoflake layers including a plurality of metal chalcogenide nanoflakes.

6. The thin film transistor of claim 1, wherein the interlayer comprises a chalcogen layer including at least one of S, Se, or Te.

7. The thin film transistor of claim 1, wherein
one surface of the interlayer is in contact with the semiconductor layer, and
an other surface of the interlayer is in contact with the source electrode or the drain electrode.

8. The thin film transistor of claim 1, wherein the interlayer is thinner than the semiconductor layer.

9. The thin film transistor of claim 1, wherein a thickness of the interlayer is greater than or equal to 1 nm and less than 10 nm.

10. The thin film transistor of claim 1, wherein the source electrode and the drain electrode comprise two or more layers including different metals.

11. A thin film transistor, comprising
a semiconductor layer,
an electrode, and
an interlayer between the semiconductor layer and the electrode, wherein
the interlayer is in contact with the semiconductor layer and the electrode, and
the interlayer comprises a chalcogen atom.

12. The thin film transistor of claim 11, wherein
the interlayer comprises a chalcogen layer, and
the chalcogen layer includes at least one of S, Se, or Te.

13. The thin film transistor of claim 12, wherein
the semiconductor layer comprises a metal chalcogenide represented by MX₂,
M is at least one of Mo, W, Nb, Ti, Ta, Pt, Pd, Co, Cr, Cu, Ni, Hf, Sn, or Re, and
X is at least one of S, Se, or Te.

14. The thin film transistor of claim 11, wherein the chalcogen atom in the interlayer is same as or different from a chalcogen element in the semiconductor layer.

15. The thin film transistor of claim 11, wherein the semiconductor layer comprises one or more metal chalcogenide monolayers.

16. The thin film transistor of claim 11, wherein the semiconductor layer comprises metal chalcogenide nanoflakes.

17. An electronic device comprising:
the thin film transistor of claim 1.

18. An electronic device comprising:
a panel including the thin film transistor of claim 1.

19. A panel for an electronic device, comprising
a substrate,
a thin film transistor array on the substrate, the thin film transistor array comprising thin film transistors,
a unit element array on the substrate, wherein
the thin film transistors include the thin film transistor of claim 1, and
the unit element array comprises a plurality of unit elements electrically connected to the thin film transistors.

20. The panel of claim 19, wherein the plurality of unit elements comprise a light emitting diode, a photoelectric conversion diode, or any combination thereof.
